(19) United States
(12) Patent Application Publication
(10) Pub. No.: US 2026/0052994 A1
(43) Pub. Date: Feb. 19, 2026

(54) STRESS RELIEF FEATURES FOR LOCALIZED DIE STRESS RELIEF

(71) Applicant: Wolfspeed, Inc., Durham, NC (US)

(72) Inventors: Thomas Harrington, Carrollton, TX (US); Neal Oldham, Apex, NC (US); Surabhi Lodha, Durham, NC (US)

(21) Appl. No.: 18/807,029

(22) Filed: Aug. 16, 2024

(51) Int. Cl. H01L 23/00; H01L 21/308; H01L 29/78

(52) U.S. Cl. CPC H01L 23/562; H01L 21/308; H10D 30/668

(57) ABSTRACT

A power semiconductor device includes a semiconductor structure comprising an active region, and a plurality of stress relief trenches in the semiconductor structure laterally between the active region and at least one edge of the semiconductor structure. The stress relief trenches respectively comprise opposing sidewalls and a dielectric material and/or a semiconductor material therebetween, and do not contribute to electrical conduction between first and second terminals of the power semiconductor device. Related devices and fabrication methods are also discussed.

### FIELD

The present disclosure is directed to power semiconductor devices, and more particularly, to increasing reliability of power semiconductor devices.

### BACKGROUND

Power semiconductor devices are used to carry large currents and support high voltages. A wide variety of power semiconductor devices are known in the art including, for example, power Metal Insulator Semiconductor Field Effect Transistors (“MISFETs,” including Metal Oxide Semiconductor FETs (“MOSFETs”)), bipolar junction transistors (“BJTs”), Insulated Gate Bipolar Transistors (“IGBTs”), Schottky diodes, Junction Barrier Schottky (“JBS”) diodes, merged p-n Schottky (“MPS”) diodes, Gate Turn-Off Thyristors (“GTOs”), MOS-controlled thyristors and various other devices. These power semiconductor devices are generally fabricated from wide bandgap semiconductor materials such as silicon carbide (SiC) or gallium nitride (GaN) based materials (herein, the term “wide bandgap semiconductor” encompasses any semiconductor having a bandgap of at least 1.4 eV). Power semiconductor devices are designed to block (in the forward or reverse blocking state) or pass (in the forward operating state) large voltages and/or currents. For example, in the blocking state, a power semiconductor device may be designed to sustain hundreds or thousands of volts of electric potential.

A conventional silicon carbide power device typically has a silicon carbide substrate, such as a silicon carbide wafer, on which an epitaxial layer structure is formed. This epitaxial layer structure (which may include one or more separate layers) functions as a drift layer or drift region of the power semiconductor device. The device typically includes an “active region,” which includes one or more “unit cell” structures that have a p-n junction and/or a Schottky junction. The active region may be formed on and/or in the drift region. The active region acts as a main junction for blocking voltage in the reverse bias direction and providing electrical conduction or current flow in the forward bias direction.

Power semiconductor devices may have a unit cell configuration in which the active region of each power semiconductor device includes a large number of individual unit cell structures that are electrically connected in parallel to function as a single power semiconductor device. In high power applications, such a power semiconductor device may include thousands or tens of thousands of unit cells implemented in a single chip or “die.” A die or chip may include a small block of semiconducting material or other semiconductor structure in which electronic circuit elements are fabricated. The semiconductor structure may or may not include an underlying substrate. Herein, the term “semiconductor structure” refers to a structure that includes one or more layers such as semiconductor substrates and/or semiconductor epitaxial layers.

Power semiconductor devices can have a lateral structure or a vertical structure. In a device having a lateral structure, the terminals of the device (e.g., the drain, gate and source terminals for a power MOSFET) are on the same major surface (i.e., upper or lower) of a semiconductor structure. In contrast, in a device having a vertical structure, at least one terminal is provided on each major surface of the semiconductor structure (e.g., in a vertical MOSFET, the source and gate may be on the upper surface of the semiconductor structure and the drain may be on the bottom surface of the semiconductor structure). For example, power Schottky diodes typically have a vertical structure where the anode contact is formed on a first major surface (e.g., the top surface) of a semiconductor structure, and the cathode contact is formed on the other major surface (e.g., the bottom surface). Vertical structures are typically used in very high power applications, as the vertical structure allows for a thick semiconductor drift layer that can support high current densities and block high voltages.

However, thermomechanical stress, which may originate from differences or mismatch in the coefficients of thermal expansion (CTE) of the semiconductor structure and the overlying metal and/or insulating layers thereon, can be significant in larger power semiconductor device chips, potentially leading to cracking and/or delamination of the overlying layers.

### SUMMARY

According to some embodiments, a power semiconductor device includes a semiconductor structure having an active region and a plurality of stress relief trenches in the semiconductor structure laterally between the active region and at least one edge of the semiconductor structure. The stress relief trenches respectively include opposing sidewalls and a dielectric material and/or a semiconductor material therebetween.

In some embodiments, the stress relief trenches are arranged in a repeating pattern and do not contribute to electrical conduction between the first and second terminals of the power semiconductor device.

In some embodiments, the semiconductor structure has a first conductivity type, and the opposing sidewalls and/or a bottom surface of the stress relief trenches have a second conductivity type that is opposite to the first conductivity type.

In some embodiments, the stress relief trenches are in an edge termination region of the semiconductor structure.

In some embodiments, the stress relief trenches are first stress relief trenches in a peripheral region of the semiconductor structure, and the device further comprises second stress relief trenches comprising opposing sidewalls and the dielectric material and/or the semiconductor material therebetween. The second stress relief trenches are in electrically inactive areas adjacent portions of the active region of the semiconductor structure.

In some embodiments, the device further comprises a plurality of conductive structures on the active region, with the second stress relief trenches extending under the conductive structures.

In some embodiments, a depth, width, and/or pitch of the second stress relief trenches are configured such that a capacitance of the active region is substantially unaffected thereby.

In some embodiments, the device further comprises a plurality of active trenches comprising opposing sidewalls and the dielectric material and/or the semiconductor material therebetween in the active region. The active trenches are configured to provide electrical conduction between the first and second terminals of the power semiconductor device. The active trenches and the stress relief trenches extend into the semiconductor structure to the same depth.

In some embodiments, the stress relief trenches comprise a plurality of continuous tracks that extend along edges and/or corners of the semiconductor structure.

In some embodiments, the stress relief trenches comprise a plurality of discontinuous segments adjacent to edges and/or corners of the semiconductor structure.

In some embodiments, a depth, width, pitch, and/or area density of a first subset of the stress relief trenches in a corner region of the semiconductor structure are greater than that of a second subset of the stress relief trenches in at least one other region of the semiconductor structure.

In some embodiments, the dielectric material comprises an oxide, a silicate glass, or air.

In some embodiments, the semiconductor material in the stress relief trenches includes a polysilicon material that defines a heterojunction with the semiconductor structure.

In some embodiments, the semiconductor material in the stress relief trenches includes one or more epitaxial layers.

In some embodiments, the power semiconductor device is a Schottky diode, a field-effect transistor, or a bipolar transistor.

In some embodiments, the semiconductor structure comprises a silicon carbide substrate and/or one or more silicon carbide epitaxial layers.

According to some embodiments, a power semiconductor device includes a semiconductor structure with an active region and a plurality of trenches in the semiconductor structure, where a first subset of the trenches is in the active region and is configured to provide electrical conduction between the first and second terminals of the power semiconductor device, and a second subset of the trenches does not contribute to the electrical conduction.

In some embodiments, the first and second subsets of the trenches extend into the semiconductor structure to the same depth.

In some embodiments, the first and second subsets of the trenches have the same width and/or are spaced apart by the same pitch.

In some embodiments, the second subset of the trenches comprises first stress relief trenches in a peripheral region of the semiconductor structure that is laterally between the active region and at least one edge of the semiconductor structure.

In some embodiments, the semiconductor structure has a first conductivity type, and opposing sidewalls and/or a bottom surface of the plurality of trenches have a second conductivity type that is opposite to the first conductivity type.

In some embodiments, the second subset of the trenches further comprises second stress relief trenches in electrically inactive areas adjacent the active region of the semiconductor structure.

In some embodiments, the device further comprises a plurality of conductive structures on the active region, with the second stress relief trenches extending under the conductive structures.

In some embodiments, the first and second subsets of the trenches include first and second dielectric materials, respectively, between the opposing sidewalls thereof. At least one of the first and second dielectric materials comprises an oxide, a silicate glass, or air.

In some embodiments, the second subset of the trenches is provided at corners of the semiconductor structure with a greater area density than along the edges of the semiconductor structure.

In some embodiments, the semiconductor structure comprises a silicon carbide substrate and/or one or more silicon carbide epitaxial layers.

According to some embodiments, a power semiconductor device includes a semiconductor structure with a drift region having a first conductivity type, and a plurality of stress relief features extending into the drift region with a depth, width, and/or pitch that are configured to vary the mechanical stress in the semiconductor structure. The stress relief features include regions of a second conductivity type that are configured to vary an electric field concentration in the semiconductor structure.

In some embodiments, the stress relief features do not contribute to electrical conduction between the first and second terminals of the power semiconductor device.

In some embodiments, the stress relief features comprise first stress relief trenches having opposing sidewalls and a first dielectric material therebetween in a peripheral region of the semiconductor structure that is laterally between an active region and at least one edge of the semiconductor structure.

In some embodiments, the first stress relief trenches are in an edge termination region, and the regions of the second conductivity type provide termination rings that extend along respective bottom surfaces of the first stress relief trenches between the opposing sidewalls.

In some embodiments, the stress relief features further comprise second stress relief trenches having opposing sidewalls and a second dielectric material therebetween in electrically inactive areas adjacent to the active region of the semiconductor structure, where at least one of the first and second dielectric materials comprises an oxide, a silicate glass, or air.

In some embodiments, the depth, width, and/or pitch of the second stress relief trenches are configured such that the capacitance of the active region is substantially unaffected thereby.

In some embodiments, the device further comprises a plurality of conductive structures on the active region, with the second stress relief trenches extending under the conductive structures.

In some embodiments, the device further comprises a plurality of active trenches in the active region configured to provide electrical conduction between the first and second terminals of the power semiconductor device, where the active trenches and the second stress relief trenches extend into the drift region to the same depth.

In some embodiments, the semiconductor structure comprises a silicon carbide substrate and/or one or more silicon carbide epitaxial layers.

According to some embodiments, a method of fabricating a power semiconductor device includes providing a semiconductor structure comprising an active region, forming a mask pattern on the semiconductor structure, and performing an etching process using the mask pattern to form a plurality of trenches in the semiconductor structure. A first subset of the trenches is in the active region, and a second subset of the trenches is laterally between the active region and at least one edge of the semiconductor structure.

In some embodiments, the second subset of the trenches does not contribute to electrical conduction between the first and second terminals of the power semiconductor device.

In some embodiments, the semiconductor structure has a first conductivity type, and the method further comprises implanting dopants of a second conductivity type into opposing sidewalls and/or bottom surfaces of the plurality of trenches after performing the etching processes.

In some embodiments, the second subset of the trenches is in an edge termination region of an inactive region, and the dopants of the second conductivity type provide termination rings that extend along the bottom surfaces of the second subset of the trenches between the opposing sidewalls.

In some embodiments, the first subset of the trenches comprises stress relief trenches that do not contribute to electrical conduction between the first and second terminals of the power semiconductor device.

In some embodiments, the method further comprises providing a plurality of conductive structures on the active region, with the stress relief trenches extending under the conductive structures.

In some embodiments, the method further comprises providing first and second dielectric materials between opposing sidewalls of the first and second subsets of the trenches, respectively, wherein at least one of the first and second dielectric materials comprises an oxide, a silicate glass, or air.

In some embodiments, the etching process forms the first and second subsets of the trenches extending into the semiconductor structure to the same depth.

In some embodiments, the etching process forms the first and second subsets of the trenches with the same width and/or the same pitch.

In some embodiments, the etching process forms the second subset of the trenches at corners of the semiconductor structure with a greater area density than along the edges of the semiconductor structure.

In some embodiments, the semiconductor structure comprises a silicon carbide substrate and/or one or more silicon carbide epitaxial layers.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIG. 1A is a schematic plan view of a power semiconductor device (shown as a MOSFET) that may include stress relief features in the semiconductor structure in accordance with some embodiments of the present disclosure.

FIG. 1B is a schematic cross-sectional view taken along line B-B′ of FIG. 1A.

FIG. 2 is a schematic cross-sectional view illustrating stress relief features in the semiconductor structure of a power semiconductor device in accordance with some embodiments of the present disclosure.

FIGS. 3A, 3B, and 3C are schematic cross-sectional views illustrating stress relief features that further provide electric field spreading in an edge termination region of the semiconductor structure in accordance with some embodiments of the present disclosure.

FIGS. 4A, 4B, and 4C are schematic cross-sectional views of a JFET including stress relief features that do not contribute to electrical conduction in an active region of the semiconductor structure in accordance with some embodiments of the present disclosure.

FIGS. 5A, 5B, and 5C are schematic cross-sectional views of a MOSFET including stress relief features that do not contribute to electrical conduction in an active region of the semiconductor structure in accordance with some embodiments of the present disclosure.

FIG. 6 is a flow diagram illustrating methods of fabricating a power semiconductor device including stress relief features in the semiconductor structure, according to some embodiments of the present disclosure.

FIGS. 7A, 7B, and 7C are enlarged schematic plan views illustrating example configurations of stress relief features in the semiconductor structure of a power semiconductor device according to some embodiments of the present disclosure.

FIGS. 8A, 8B, and 8C are enlarged schematic plan views illustrating example configurations of stress relief features in the semiconductor structure between adjacent semiconductor dies according to some embodiments of the present disclosure.

FIGS. 9A, 9B, 9C, and 9D are enlarged schematic plan views illustrating example configurations of stress relief features in the semiconductor structure of a power semiconductor device according to some embodiments of the present disclosure.

FIGS. 10A, 10B, 10C, and 10D illustrate example configurations of stress relief features according to some embodiments of the present disclosure relative to that of a comparative example and simulation data based thereon.

FIG. 11 is a table comparing performance of the example configurations of stress relief features according to some embodiments of the present disclosure and the comparative example shown in FIGS. 10A to 10D.

### DETAILED DESCRIPTION OF EMBODIMENTS

Embodiments of the present disclosure may arise from realization that relieving stress in a semiconductor structure or die may be advantageous in increasing reliability in power semiconductor devices. For example, metal structures (including conductive pads and/or buses) that are deposited or otherwise formed on a semiconductor structure may result in mechanical stress, e.g., due to differences in respective coefficients of thermal expansion (CTE) of the semiconductor and metal materials. In particular, interfaces between the semiconductor structure and metal lines with relatively high aspect ratios (e.g., gate buses with lengths (˜3-4 mm) that are significantly greater than widths (˜30 μm)) may impart significant mechanical stress on the underlying semiconductor structure. Also, higher stress may be present at edges and/or corners of the semiconductor structure, which may result in warpage.

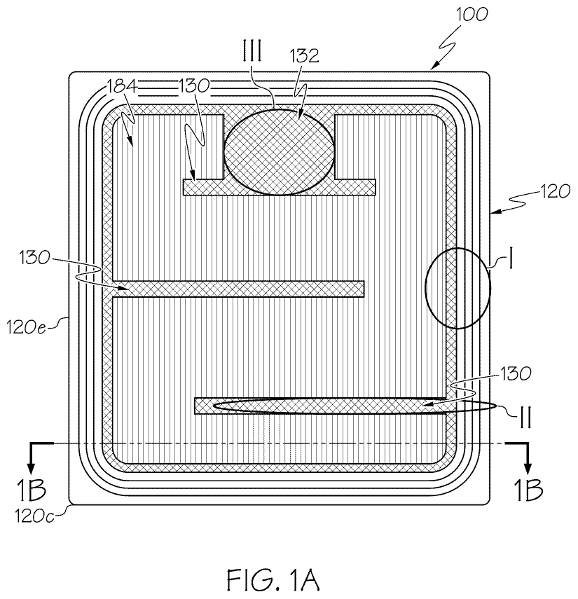

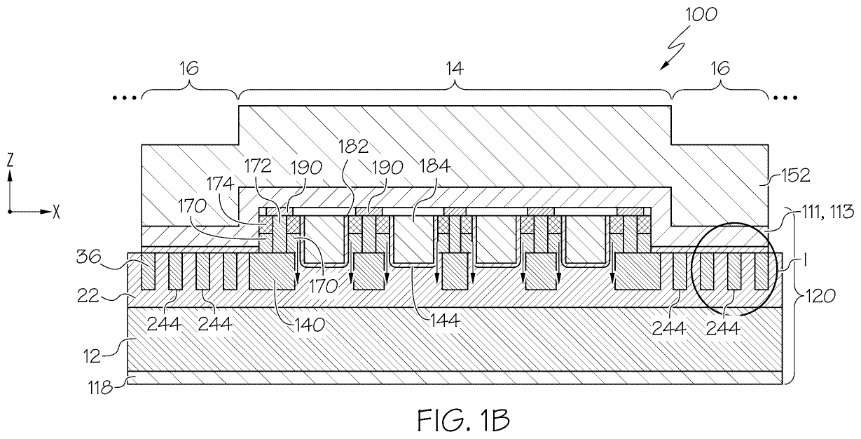

Embodiments of the present disclosure provide features that are configured to reduce mechanical stress in the semiconductor structure, referred to herein as stress-relief features or structures (such as stress relief trenches). FIG. 1A is a schematic plan view of a power semiconductor device 100 that may include stress relief features in accordance with some embodiments of the present disclosure. FIG. 1B is a schematic cross-sectional view of the power semiconductor device 100 taken along line B-B′ of FIG. 1A. While primarily discussed herein with reference to MOSFETs, it will be appreciated that specific layer structures, doping concentrations, materials, conductivity types and the like that are shown in FIGS. 1A-1B and/or described below are merely provided as examples for purposes of illustration rather than limitation. For example, power semiconductor devices including stress relief features as described herein may also include other field effect transistor devices (e.g., JFETs), bipolar transistor devices (e.g., IGBTs), or Schottky diodes.

In FIGS. 1A and 1B, the power semiconductor device 100 is illustrated as a MOSFET having a “unit cell” structure in which the active region includes a plurality of individual MOSFETs that are disposed in parallel to each other and that together function as a single power MOSFET. The power MOSFET 100 includes a semiconductor structure 120 in which an active region 14 within an edge termination region 16 (or more generally, a peripheral region 16) is defined. The edge termination region 16 may help reduce undesired electric field crowding effects that may occur at the edges of the active region 14. The edge termination region 16 may, but does necessarily, completely or substantially surround the active region 14. A drift layer 22 extends along the top side of a substrate 12 to define the semiconductor structure 120.

The semiconductor structure 120 may include wide band-gap semiconductor materials. In the example power MOSFET 100, the substrate 12 and the drift layer 22 of the semiconductor structure 120 are silicon carbide (SiC)-based, for example, a SiC substrate 12 and a SiC drift layer 22 (e.g., a 4H-SiC layer) epitaxially grown thereon with a uniform or graded doping concentration. The substrate 12 and the drift layer 22 are not limited to SiC, and may be formed from other material systems, such as, for example, Group III nitrides (e.g., GaN), gallium arsenide (GaAs), silicon (Si), germanium (Ge), silicon germanium (SiGe), and the like. The drift layer 22 may be substantially uniformly doped or doped in a graded fashion, e.g., from being relatively more heavily doped (e.g., to define a current spreading layer) proximate the substrate 12 to being more lightly doped opposite the substrate 12. The peripheral region 16 substantially surrounds the active region 14, and may include an edge termination portion or region, which may be recessed (as illustrated) or coplanar relative to the top surface of the drift layer 22. The edge termination region 16 includes a plurality of guard rings 36. The guard rings 36 may be formed by heavily doping the corresponding portions of the recessed portions of the drift layer 22 with a doping material of second conductivity type (e.g., p-type), which is opposite to a first conductivity type (e.g. n-type) of the drift layer 22. However, it will be understood that edge termination structures other than guard rings 36 may be used.

Spaced apart shielding regions 140 of the second conductivity type may be formed in the upper surface of the drift layer 22 in the active region 14, and gate trenches 144 (also referred to herein as active trenches 144) are formed extending through well regions 170 in the drift layer 22. The gate trenches 144 may have a U-shaped cross-section in some embodiments, as shown in FIG. 1B. A gate insulating layer 182 such as a silicon oxide layer is formed on the bottom surface and sidewalls of each gate trench 144. A gate electrode 184 is formed on the gate insulating layer 182 in the respective gate trenches 144. The gate electrodes 184 may comprise, for example, a semiconductor or a metal material. Heavily-doped silicon carbide source regions 174 may be formed in upper portions of the well regions 170. Source contacts 190 (e.g., ohmic contacts) may be formed on the heavily-doped n-type source region 174. The source contacts 190 may be electrically connected (e.g., by a top side metallization or other metal overlayers, which are electrically isolated from the gate buses 130 and gate bond pad 132) to form a single source electrode.

The drift region 22 and the substrate 12 together act as a common drain region for the power MOSFET 100. A drain contact 118 may be formed on the lower surface of the substrate 212 below both the active region 14 and the edge termination region 16. While not shown, one or more additional layers may be formed on the drain contact 118 to define a backside metal stack for attachment to a package submount. The backside metal stack may include, but is not limited to, multi-layer metal stacks including titanium (Ti), titanium tungsten (TiW), gold (Au), platinum (Pt), nickel (Ni), and/or aluminum (Al).

As shown in FIG. 1A, a gate bond pad 132 may be electrically connected to each gate electrode or gate finger 184 by conductive structures 130. The conductive structures 130 may provide one or more gate buses that electrically connect the gate fingers 184 to the gate bond pad 132. The conductive structures 130 may comprise, for example, a polysilicon pattern in some embodiments, although metal or other conductive patterns could also be used. The conductive structures 130 may also provide redistribution layers (RDL) in some embodiments.

Still referring to FIG. 1A, the MOSFET 100 includes a top-side metallization structure that electrically connects source regions in the semiconductor structure 120 of the MOSFET 100 to an external device. The top-side metallization structure is not shown in FIG. 1A, as significant portions of the top-side metallization structure are covered by one or more passivation layers 111 and a protective overcoating layer 152. The passivation layer(s) 111 may be nitride-based (e.g., a SiN layer), and may function as a conformal coating that protects the underlying layers from adverse environmental conditions, and may define portions of a bonding surface of the semiconductor structure 120.

A protective overcoating (e.g., a polyimide layer) 152 is provided on the bonding surface, for further protection against damage (e.g., arcing, moisture, etc.). The polyimide layer or other protective overcoating 152 may protect the semiconductor structure 120 underneath, and may provide a leveling effect for appropriate handling in following manufacturing steps. Additional layers (e.g., an intermetallic dielectric layer and a field oxide layer) may also be provided between the semiconductor structure 120 and the passivation layer 111 or protective overcoating 152 thereon.

Source bond pads (not shown) may be provided by portions of the top-side metallization structure that are exposed through openings in the protective overcoating 152 in some embodiments. Bond wires (not shown) may be used to connect the gate bond pad 132 and the source bond pads to external circuits or the like.

In FIGS. 1A and 1B, differences or mismatch in the coefficients of thermal expansion (CTE) of the materials of the semiconductor structure 120 and the layers formed thereon may result in mechanical stress along the interfaces therebetween. For example, metal structures (including conductive pads 132 and/or buses 130, particularly with relatively high aspect ratios) and/or insulating structures (including passivation layers 111, interlayer dielectric layers 113, protective overcoating 152, and/or encapsulation thereon) that are deposited or otherwise formed on semiconductor structure 120 may result in mechanical stress along respective interfaces with the semiconductor structure 120, due to the CTE mismatch between the various materials.

Some embodiments of the present disclosure provide stress relief features that are configured to reduce stress that would otherwise propagate up from the surface of the semiconductor structure 120 and cause fracturing or movement of features 130, 132, 111, 152 on or above the surface (e.g., during thermal cycling). Without such stress relief features, insulators and/or conductors above the surface can be fractured and/or cracked. Conductors in particular may be lifted and physically moved across the surface of the semiconductor structure.

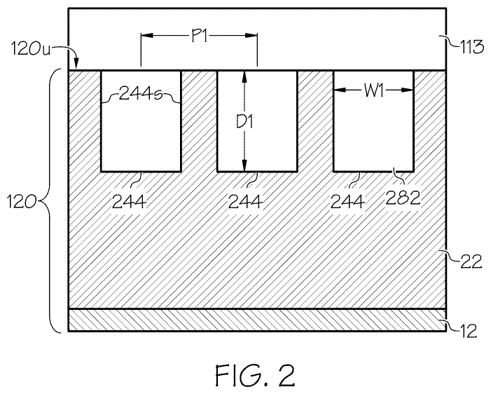

FIG. 2 is a schematic cross-sectional view illustrating stress relief features 244 in the semiconductor structure 120 of a power semiconductor device in accordance with some embodiments of the present disclosure. As shown in FIG. 2, the stress relief features or structures may be implemented by a plurality of (i.e., two or more) trenches or corrugations 244 in a surface (e.g., the upper surface 120u) of the semiconductor structure 120, to create localized stress-relieved regions. The stress relief structures 244 may be provided in a regular or repeating pattern in the semiconductor structure 120 (e.g., a periodic or aperiodic pattern, rather than random pattern) with a depth D1 (e.g., about 2 μm to 20 μm), width W1 (e.g., about 2 μm to 10 μm), and/or pitch P1(e.g., about 2 μm to 10 μm) configured to reduce or otherwise vary mechanical stress in the semiconductor structure 120, but do not contribute to electrical conduction between first and second terminals (e.g., the source terminal 190 and the drain terminal 118) of the power semiconductor device 100.

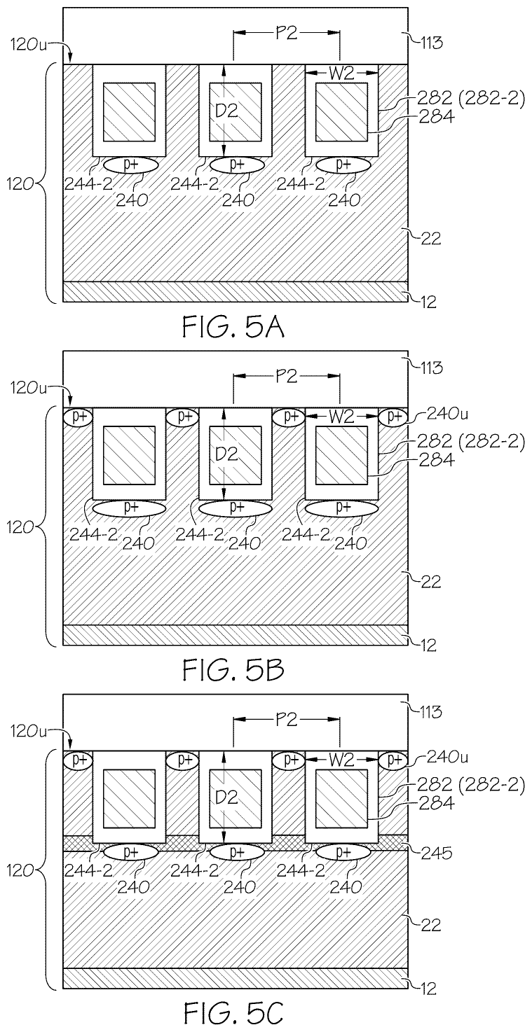

In the example of FIG. 2, the stress relief structures are illustrated as stress relief trenches 244 that are etched into a surface 120u of the semiconductor structure 120 and extend into the drift region 22 (or other epitaxial layers) and/or into the underlying substrate 12. The stress relief trenches 244 are illustrated as rectangular in cross-section, but may be formed in other shapes (e.g., triangular, semi-elliptical) in cross-section, and may extend continuously (in tracks) or discontinuously (in segments) in plan view. The stress relief trenches 244 respectively include opposing sidewalls 244s and one or more dielectric materials 282 therebetween. The stress relief trenches 244 may be completely or partially filled with the dielectric material(s) 282, such as silicate glass (e.g., borophosphosilicate glass BPSG), oxide (e.g., SiO₂), or air. In some embodiments, the stress relief trenches 244 may further include semiconductor materials (e.g., polysilicon) between the opposing sidewalls 244s (as shown in FIGS. 5A-5C). The respective depths D1 of the stress relief trenches 244 (relative to the upper surface 120u of the semiconductor structure) may be adjusted or may differ in different regions (e.g., 14, 16, 120e, 120c) so as to vary the mechanical stress that is present in the different regions of the semiconductor structure 120. An interlayer dielectric layer 113 may be formed along the upper surface 120u of the semiconductor structure 120, and may extend on the stress relief trenches 244 and the dielectric material(s) 282.

The stress relief features 244 may be implemented in any of the areas I, II, or III of the power semiconductor device 100 shown in FIG. 1A that do not contribute to electrical conduction between the source and drain terminals. As used herein, regions that do not contribute to electrical conduction between the source and drain terminals may be referred to as “outside” the active region 14. Areas outside the active region 14 may thus include the peripheral region 16 that extends around the active region 14, and/or electrically inactive areas that are adjacent or surrounded by portions of the active region 14. That is, the stress relief features 244 may be provided in the peripheral region 16 laterally between the active region 14 and at least one edge 120e of the semiconductor structure 120 (e.g., first stress relief trenches 244-1 described herein), and/or in other electrically inactive areas adjacent portions of the active region 14 of the semiconductor structure 120 (e.g., second stress relief trenches 244-2 described herein). In some embodiments, stress relief structures may be provided outside not only the active region 14, but also outside the edge termination region 16. For example, to avoid interference with conventional die structures such as termination rings 36, stress relief features 244 can be provided in regions of the semiconductor structure 120 that are free of other device geometries or features. In particular, the stress relief features 244 can be provided along peripheral edges 120e or corners 120c of the upper surface 120u of the semiconductor structure 120 (where stress may be comparatively higher than other regions of the semiconductor structure 120; see FIGS. 7A-7C), or even in scribe street regions 158 extending along or around the edges 120c of the semiconductor structure 120 (see FIGS. 8A-8C). Such stress relief features 244 may also be referred to herein as dedicated stress relief structures.

Regardless of location in the peripheral region 16 or otherwise outside the active region 14, the stress relief structures 244 shown in FIG. 2 may include similar or identical structures, dimension(s) (including length, width, depth, and/or pitch), and/or materials as the active conduction structures that provide electrical conduction between first and second terminals 190 and 118 of the device 100. For example, the stress relief structures 244 may be similar or identical in structure, materials (including dielectric materials 282), and/or dimension(s) to the structure, materials (including dielectric materials 182), and/or dimension(s) of the active trenches 144 (e.g., MOSFET trenches or JFET trenches) in the active region 14 of the semiconductor structure 120 shown in FIG. 1B.

In some embodiments, the stress relief structures 244 may be implemented as dual-purpose stress relief structures, which are configured not only to vary a mechanical stress in the semiconductor structure 120, but are also configured to vary an electric field concentration or distribution in the semiconductor structure 120. For example, the stress relief trenches 244 may be formed in the edge termination region 16 in one or more ring-shapes (e.g., corresponding to locations of the guard rings 36) that extend around a periphery of the active region 14 in plan view, and may be doped so as to provide both electric field spreading and mechanical stress relief.

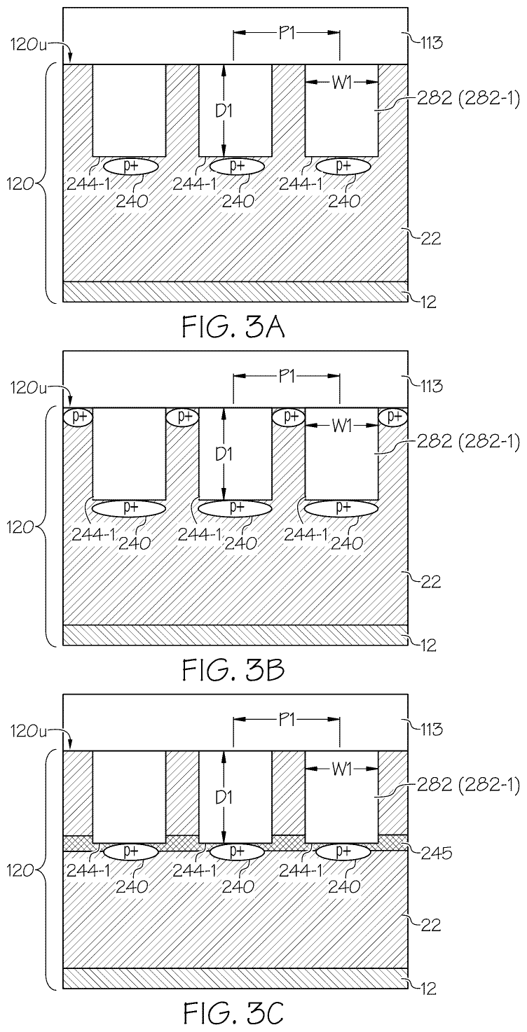

FIGS. 3A, 3B, and 3C are schematic cross-sectional views illustrating stress relief features that further provide electric field spreading in an edge termination region of a semiconductor structure of a power semiconductor device in accordance with some embodiments of the present disclosure. As shown in FIGS. 3A to 3C, the semiconductor structure 120 includes a plurality of stress relief structures 244 extending into the drift region 22 with a depth D1, width W1, and/or pitch P1 configured to vary mechanical stress in the semiconductor structure 120. In addition, the stress relief structures 244 include regions of a second (e.g., p−) conductivity type that is opposite the first (e.g., n−) conductivity type type) of the drift region 22, and are configured to vary the electric field distribution in the semiconductor structure 120.

In particular, stress relief trenches 244-1 may be implemented in the edge termination region 16, which surrounds the active region 14. The stress relief trenches 244-1 may be etched into the semiconductor structure 120 using one or more mask patterns, and may be implanted with dopants to form guard/termination regions 240/240u (e.g., p+ guard/termination rings). In some embodiments, the stress relief trenches 244-1 may be etched into the semiconductor structure 120 before the implantation process, so that no additional masks are required. A dielectric material 282 is formed in the stress relief trenches 244-1 between opposing sidewalls 244s thereof.

As such, as shown in FIG. 3A, the bottom surface of the stress relief trenches 244-1 may include highly-doped regions 240 of a second conductivity type (e.g., p+ regions), which is opposite to the first conductivity type (e.g., n−) of the drift region 22. The highly-doped second conductivity type regions 240 are configured to vary an electric field concentration in the semiconductor structure 120. FIG. 3B illustrates a variation where the upper surface 120u of the semiconductor structure 120 between the stress relief trenches 244-1 also includes highly-doped regions of the second conductivity type (e.g., p+ regions) 240u. FIG. 3C illustrates a further variation where a junction termination extension (JTE) region 245 of the second conductivity type electrically couples the termination regions 240 along the bottom surfaces of the stress relief trenches 244-1. The JTE region 245 may have a lower doping concentration (e.g., p⁻) of the second conductivity type as compared to the termination regions 240, and may provide more uniform shielding.

The stress relief structures 244 may also be implemented within electrically inactive areas that are adjacent portions of the active region 14 (e.g., under a gate bus 130 and/or gate pad 132), in addition to (or as an alternative to) being implemented the peripheral regions 16 of the semiconductor structure 120 (as shown in FIG. 2 and FIGS. 3A-3C). The stress relief structures 244 may thus include first stress relief trenches 244-1 that are formed in the peripheral region 16 of the semiconductor structure 120, and second stress relief trenches 244-2 that are formed in the electrically inactive areas adjacent portions of the active region 14 of the semiconductor structure 120.

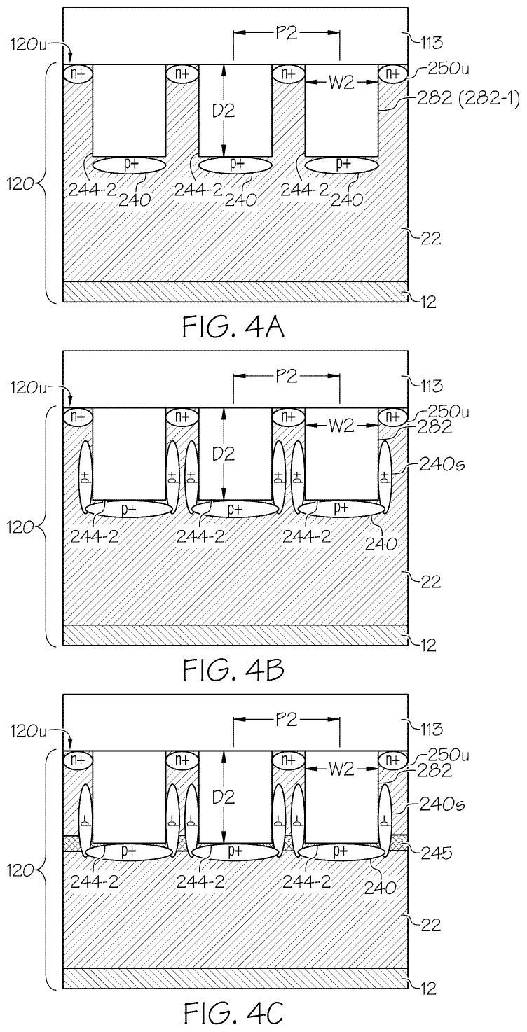

FIGS. 4A, 4B, and 4C are schematic cross-sectional views of a JFET including stress relief features in an active region 14 of the semiconductor structure 120 in accordance with some embodiments of the present disclosure. FIGS. 5A, 5B, and 5C are schematic cross-sectional views of a MOSFET including stress relief features in an active region 14 of the semiconductor structure 120 in accordance with some embodiments of the present disclosure.

In particular, while active trenches 144 may be provided in the active region in conventional trench MOSFET unit cells 100 as shown in FIG. 1A (or similarly, in trench JFET unit cells), stress relief structures 244 may also be provided in specific portions of the active region 14 that may be subjected to higher stress (in comparison to at least one other region of the semiconductor structure 120), thereby relieving stress before it can build to a level sufficient to damage one or more elements on (or layers of) the active region 14. For example, stress relief trenches 244-2 may be provided in the area II or III of the active region 14, as shown in FIG. 1A. In particular, the stress relief trenches 244-2 may be implemented under the conductive structures 130, 132, which may locally increase stress in the active region 14 due to CTE mismatch match between materials of the conductive structures 130, 132 (e.g., metal, polysilicon) and the underlying semiconductor structure 120.

As shown in FIGS. 4A to 4C and 5A to 5C, the semiconductor structure 120 includes a plurality of stress relief trenches 244-2 extending into the drift region 22 with a depth D2, width W2, and/or pitch P2 configured to vary mechanical stress in the semiconductor structure 120. The depth D2, width W2, and/or pitch P2 of the stress relief trenches 244-2 in electrically inactive areas adjacent portions of the active region 14 may be the same as or different than the depth D1, width W1, and/or pitch P1 of the stress relief structures 244-1 in the peripheral region 16. The stress relief trenches 244-2 also include regions 240 of a second (e.g., p−) conductivity type that is opposite the first (e.g., n−) conductivity type type) of the drift region 22 at bottom surfaces of the stress relief trenches 244-2.

In particular, as noted above, the stress relief trenches 244-2 in electrically inactive areas adjacent portions of the active region 14 may be similar or identical to (e.g., formed using one or more common fabrication steps as) the active trenches 144. For example, in the JFET embodiments shown in FIGS. 4A to 4C, the illustrated stress relief trenches 244-2 may include dielectric material(s) and/or doped regions that are similar to the JFET mesas in the active region. As such, a dielectric material 282 may be provided in the stress relief trenches 244-2 between opposing sidewalls 244s thereof, highly-doped regions of the first conductivity type (e.g., n+ regions) 250u may be provided in the upper surface 120u of the semiconductor structure 120 between the stress relief trenches 244-2, and highly-doped regions of the second conductivity type (e.g., p+ regions) 240 may be provided at bottom surfaces of the stress relief trenches 244-2, as shown in FIG. 4A. FIG. 4B illustrates a variation that further includes highly doped (e.g., p+) regions 240s of the second conductivity type on opposing sidewalls 244s of the stress relief trenches 244-2, which may provide sidewall gates. FIG. 4C illustrates a further variation including a JTE region 245 of the second conductivity type that electrically couples the respective highly doped bottom regions 240 and sidewall regions 240s of the stress relief trenches 244-2.

Likewise, in the MOSFET embodiments shown in FIGS. 5A to 5C, the illustrated stress relief trenches 244-2 may include dielectric material(s), gate material(s), and/or doped regions that are similar to the MOSFET gate trenches in the active region. In particular, a dielectric material (e.g., an oxide layer) 282 and a gate material (e.g., a polysilicon material) 284 may be provided in the stress relief trenches 244-2 between opposing sidewalls 244s thereof, and highly-doped regions of the second conductivity type (e.g., p+ regions) 240 may be provided at bottom surfaces of the stress relief trenches 244-2, as shown in FIG. 5A. FIG. 5B illustrates a variation that further includes highly doped (e.g., p+) regions 240u of the second conductivity type in the upper surface 120u of the semiconductor structure 120 between the stress relief trenches 244-2, while FIG. 5C illustrates a further variation that includes a JTE region 245 of the second conductivity type that electrically couples respective bottom regions 240 of the stress relief trenches 244-2.

The stress relief trenches 244-1 in the peripheral region 16 may include a same or different dielectric material therein than the stress relief trenches 244-2 in electrically inactive areas adjacent portions of the active region 14. For example, the stress relief trenches 244-1 in the peripheral region 16 may include a first dielectric material 282-1, while the stress relief trenches 244-2 in electrically inactive areas adjacent portions of the active region 14 may include a second dielectric material 282-2 that is different from the first dielectric material 282-1. At least one of the first 282-1 and second 282-2 dielectric materials may include an oxide (e.g., SiO₂), a silicate glass (e.g., BPSG), or air.

The active trenches 144 and the stress relief trenches 244-2 in electrically inactive areas adjacent portions of the active region 14 may be formed using a same or common masking and/or etching process, such that the active trenches 144 and the stress relief trenches 244 extend into the semiconductor structure 120 to the same depth D2 in some embodiments. Likewise, the active trenches 144 and the stress relief trenches 244-2 may have the same width W2 and/or may be spaced apart by the same pitch P2 in some embodiments. As such, a plurality of trenches 144, 244 may be formed in electrically inactive areas adjacent portions of the active region 14 and in the peripheral region 16 of the semiconductor structure, where a first subset of the trenches 144, 244 may provide active trenches 144 that are configured for electrical conduction between the first terminal 190 and the second terminal 118 of the power semiconductor device, and a second subset of the trenches 144, 244 may provide stress relief trenches 244 (including 244-1 and 244-2) that do not contribute to the electrical conduction. The dielectric materials 282 and/or the gate materials 284 formed in the stress relief trenches 244 may be identical to the dielectric materials 182 and the gate materials 184 formed in the active trenches 144 in some embodiments.

The stress relief trenches 244 may be provided in corners 120c and/or along the edges 120e or perimeter of the semiconductor structure 120 with various patterns, and/or under conductive structures or buses, for stress relief purposes. Providing stress relief structures 244 that are similar to the structures 144 formed in the active region 14 may reduce cost and complexity in device fabrication. The stress relief structures 244 shown in FIGS. 3A to 5C may thus allow for case of implementation into existing fabrication processes, for example, in planar MOSFETs/IGBTs, trench MOSFETs/IGBTs, and trench JFETs, as well as in devices that use either planar P+ or trench P+ termination, Schottky diodes, or any large die including a plurality of unit cell structures.

While implementing the stress relief trenches 244-1, 244-2 similarly to active trenches 144 (e.g., in depth, width, filling dielectric, and/or pitch) used in the active region 14 may be advantageous with respect to uniformity and/or complexity in manufacturing, embodiments of the present disclosure are not so limited. That is, in some embodiments, the stress relief structures 244 may be different from (e.g., unrelated in structure and/or dimensions in comparison to) the active conduction structures 144 in the active region 14 of the semiconductor structure 120. For example, different dielectric materials 282 (including multiple insulating materials) may be used to fill the stress relief trenches 244-1, 244-2 as compared to the dielectric material 182 formed in the trenches 144 of the active region 14.

Likewise, stress relief structures 244 of different shapes and sizes may be used in electrically inactive areas adjacent portions of the active region 14, in the peripheral region 16, and/or in different portions of either. For example, the stress relief trenches 244-2 in electrically inactive areas adjacent portions of the active region 14 may have similar structures, dimensions, and/or laterally spacings/pitch as the active conduction structures 144, while stress relief trenches 244-1 in the peripheral region 16 and/or otherwise along the edges 120e of the semiconductor structure 120 may have different dimensions and/or may be spaced apart with different pitch(es) than the active conduction structures 144 of the active region). As such, the stress relief structures 244 can be designed and optimized (e.g., in depth, width, length, aspect ratio, spacing) for increased or maximum stress reduction, without being constrained by parameters of the active conduction structures 144, which may be configured for device performance.

The configuration and/or placement of the stress relief structures 244 in the semiconductor structure 120 may also be configured to avoid undesired or unintended electrical effects on device performance, in particular, without substantially affecting electrical characteristics of the active region 14. For example, stress relief trenches 244-2 that are filled with a dielectric material 282 but are wider and/or deeper than the active trenches 144 may introduce additional capacitance, which may be detrimental to performance. As such, the stress relief trenches 244-2 in electrically inactive areas adjacent portions of the active region 14 may be formed with a depth D2, width W2, and/or pitch P2 such that the capacitance of the active region 14 is substantially unaffected. For example, the depth D2, width W2, and/or pitch P2 of the stress relief trenches 244-2 may be smaller than those of the active trenches 144 in one or more dimensions. More generally, the stress relief structures 244 may be configured to vary or reduce mechanical stress int semiconductor structure 120 without substantially affecting electrical characteristics (e.g., capacitance or conductivity) of the active region 14 of the power semiconductor device 100.

Whether or not the stress relief structures 244 are structurally similar to some active conduction structures 144 of the power semiconductor device 100, the stress relief structures 244 do not contribute to electrical conduction between device terminals 190, 118 or otherwise do not function as active cells. As noted above, the stress relief structures 244 may be electrically inactive (also referred to herein as dedicated stress relief structures), or may provide electrical functionality (e.g., electric field spreading in the edge termination region; also referred to herein as dual-purpose stress relief structures).

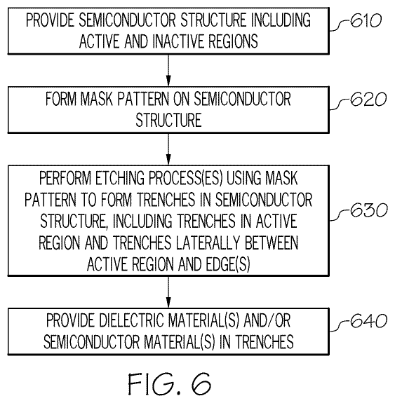

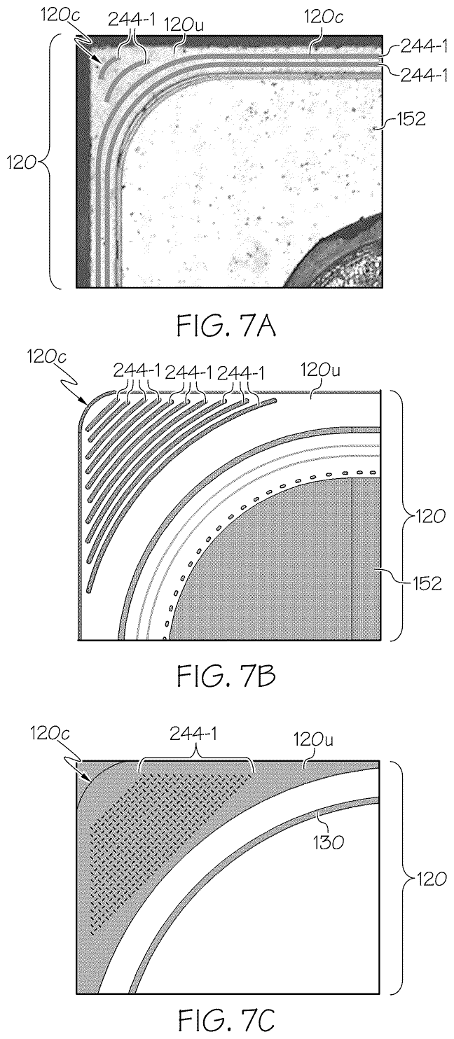

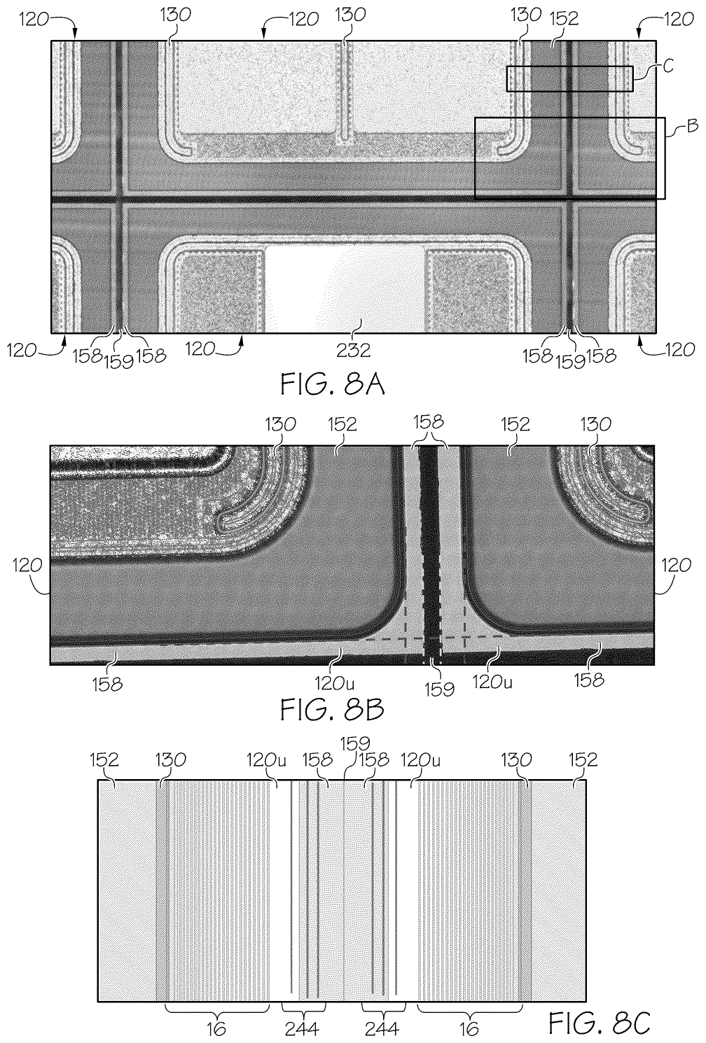

FIG. 6 is a flow diagram illustrating methods of fabricating a power semiconductor device including stress relief structures in a semiconductor structure, according to some embodiments of the present disclosure. As shown in FIG. 6, the methods include providing a semiconductor structure 120 with an active region 14 and an inactive region (block 610), forming a mask pattern on the semiconductor structure 120 including patterns or openings that expose portion(s) of the active region 14 and the peripheral region 16 (block 620), and performing one or more etching processes using the mask pattern to form a plurality of trenches 144, 244 in the upper surface 120u of the semiconductor structure 120 (block 630).

A first subset of the trenches 144, 244 includes active trenches 144 that are in the active region 14 and are configured to provide electrical conduction between the first terminal 190 and the second terminal 118 of the power semiconductor device. A second subset of the trenches 144, 244 include stress relief trenches 244 that do not contribute to the electrical conduction between the first terminal 190 and the second terminal 118. The stress relief trenches 244 include first stress relief trenches 244-1 in the peripheral region 16 (that is, laterally between the active region 14 and at least one edge 120e of the semiconductor structure 120), and second stress relief trenches 244-2 in electrically inactive areas adjacent portions of the active region 14.

The etching process(es) (at block 630) may form the active trenches 144 and the stress relief trenches 244 extending into the semiconductor structure 120 to a same depth. In some embodiments, the etching process(es) (at block 630) may be configured to form the active trenches 144 stress and the relief trenches 244 with the same width and/or pitch. The area density (and depth, width, and/or pitch) of the stress relief trenches 244 may be different in different regions of the semiconductor structure. For example, stress relief trenches 244-1 formed at corner portions 120c of the semiconductor structure 120 (which may be subjected to higher stress levels) may have different shapes, different depths, and/or a different density than stress relief trenches 244-1 along edge portions 120e of the semiconductor structure 120 or stress relief trenches 244-2 in electrically inactive areas adjacent portions of the active region 14. In some embodiments, the stress relief trenches 244-2 may have the same pitch P2 (and/or other critical dimensions) as the active trenches 144, while the stress relief trenches 244-1 in the peripheral region 16 may have a different pitch P1. Likewise, the stress relief trenches 244-1 in the peripheral region 16 may have greater widths W1 than the widths W2 of the stress relief trenches 244-2 in electrically inactive areas adjacent portions of the active region 14 (which may be similar to the widths of the active trenches 144 or otherwise configured so as to avoid unintended effects on the electrical characteristics of the active region 14).

In some embodiments, the method may further include implanting dopants of a second conductivity type (different than a first conductivity type of the semiconductor structure 120 or drift region 22 thereof) into the trenches 144, 244 (e.g., into opposing sidewalls 244s and/or the bottom surface of the plurality of trenches 144, 244), so as to form doped regions 240 after performing the etching process(es) (at block 630). Such doped regions 240 may be configured to vary electric field concentration or distribution in the semiconductor structure 120 such that the stress relief trenches 244 may be dual-purpose features.

Still referring to FIG. 6, one or more dielectric materials 182, 282 and/or semiconductor materials (such as polysilicon) are formed in the trenches 144, 244 (block 640). For example, dielectric materials 182 and 282 may be deposited to fill the active trenches 144 and the stress relief trenches 244, respectively, and may be removed from areas outside the trenches 144 and 244 (e.g., using a chemical-mechanical polishing process). The dielectric materials 182 and 282 formed in the trenches 144 and 244 in electrically inactive areas adjacent portions of the active region 14 and in the peripheral region 16, respectively, may be the same material (which may provide processing efficiencies) or may be different materials. Likewise, in some embodiments, a first dielectric material 282-1 may be formed in the stress relief trenches 244-1 in the peripheral region 16, while a second dielectric material 282-2 may be formed in the stress relief trenches 244-2 in electrically inactive areas adjacent portions of the active region 14, where the dielectric materials 282-1, 282-2 may be the same material or may be different materials. The dielectric material(s) 182, 282-1, 282-2 described herein may be oxide (e.g., SiO2), silicate glass (e.g., BPSG), or air.

However, embodiments of the present disclosure are not limited to these materials, and other dielectric and/or semiconductor materials may be formed in the trenches 144 and 244. For example, doped or undoped polysilicon (e.g., 284) may be formed in the stress relief trenches 244, in combination with the dielectric materials 282 (e.g., as shown in FIGS. 5A to 5C). When embedded in a dielectric material 282, the semiconductor material(s) in the stress relief trenches 244 may be electrically floating, or may be electrically connected to one of the device terminals (e.g., coupled to the source terminal 190). In other embodiments, the semiconductor material(s) may be formed directly in the stress relief trenches 244, without dielectric materials therein (e.g., forming a heterojunction with the semiconductor structure 120, such as a polysilicon-silicon carbide heterojunction). In some embodiments, a selective epitaxy process may be used to form the semiconductor material(s) as epitaxial layers in the stress relief trenches 244.

An interlayer dielectric material 113 may be subsequently formed on the trenches 144 and/or 244. Conductive structures 130 may be further formed on the active region 14, such that the stress relief trenches 244-2 extend under the conductive structures 130. The conductive structures 130 may include conductive buses 130 (e.g., gate buses/runners/connectors that longitudinally extend on the active region 14), redistribution layers, and/or conductive pads 132 (e.g., a gate pad or source metal of the power semiconductor device).

As shown in FIG. 6, the stress relief trenches 244 (e.g., in electrically inactive areas adjacent portions of the active region 14 or in the peripheral region 16) may thereby be formed using one or more of the same masking, patterning, and/or etching processes that are used in fabrication of active trenches 144 of a semiconductor die. As such, the stress relief trenches 244 may be identical to or different from (in depth, width, pitch, and/or filling dielectric) the active trenches 144 in the active region 14, thereby integrating stress relief functionality without increasing manufacturing complexity.

FIGS. 7A, 7B, and 7C are enlarged schematic plan views illustrating example configurations of stress relief features in the semiconductor structure of a power semiconductor device according to some embodiments of the present disclosure. In particular, FIGS. 7A-7C illustrate dedicated stress relief trenches 244-1 that are provided along the edges 120c and corners 120c of the upper surface 120u of the semiconductor structure 120, as these regions 120c, 120c may exhibit comparatively higher stress than other regions of the semiconductor structure 120, and thus, may benefit most from stress reduction.

As shown in FIGS. 7A and 7B, the stress relief trenches 244-1 may be implemented as striped or continuous tracks that extend along edges 120e and/or corners 120c of the upper surface 120u of the semiconductor structure 120. In the example of FIG. 7A, the stress relief trenches 244-1 continuously extend along both the edges 120e and corners 120c of the semiconductor structure 120, while in the example of FIG. 7B, the stress relief trenches 244-1 are arranged in a pattern at the corners 120c of the semiconductor structure 120, with extension lengths that sequentially increase with distance from the corners 120c.

As shown in FIG. 7C, the stress relief trenches 244-1 may be alternatively implemented as discontinuous segments adjacent to edges 120e and/or corners 120c of the upper surface 120u of the semiconductor structure 120. In particular, the example of FIG. 7C illustrates that the stress relief trenches 244-1 are provided as a pattern of trench segments with varying orientations at the corners 120c of the semiconductor structure 120. The pattern shown in FIG. 7C is by way of example only, and the trench segments may have other shapes (e.g., slot shapes with rounded edges, cylindrical shapes, polygonal shapes) and may be arranged in other patterns in plan view, as may be beneficial for stress relief.

An area density of the stress relief features 244 may also vary at different regions of the semiconductor structure 120. For example, the stress relief features 244 may be provided with higher or greater area density in the corner regions 120c of the upper surface 120u than along laterally extending edge regions 120e, as stress may be comparatively higher in the corner regions 120c. That is, a depth, width, pitch, and/or area density of a first subset of the stress relief trenches 244 in a corner region 120c of the semiconductor structure 120 may be greater than that of a second subset of the stress relief trenches 244 in at least one other region (e.g., along an edge 120c) of the semiconductor structure 120.

FIGS. 8A, 8B, and 8C are enlarged schematic plan views illustrating example configurations of stress relief features in portions of peripheral regions 16 between adjacent semiconductor dies or structures 120, according to some embodiments of the present disclosure. In particular, FIG. 8A is an enlarged plan view illustrating dicing streets or scribe lines 158 (also referred to as saw streets 158) between multiple adjacent semiconductor dies or structures 120, FIG. 8B is an enlarged view of region B (illustrating saw streets 158 between corners of two semiconductor structures 120) of FIG. 8A, and FIG. 8C is an enlarged view of region C (illustrating the saw street between edges 120e of two semiconductor structures 120) of FIG. 8A.

As shown in FIGS. 8A to 8C, in some embodiments, the stress relief structures 244 may be provided in or adjacent the saw streets or scribe lines 158 that are used for singulation of adjacent dies (e.g., along outer edges 120e of the semiconductor structures 120, both in the surface 120u and in the saw streets 158). In detail, the saw streets 158 may be exposed by openings in the protective overcoating 152, and a portion 159 of the saw street 158 may be removed by dicing operations to singulate adjacent semiconductor structures 120, thereby defining respective semiconductor dies. A width of the removed portion 159 may be referred to as the saw kerf, and may correspond or may be approximately equal to a width of the saw blade that is used in the dicing operations. FIGS. 8A to 8C illustrate that stress relief structures 244 as described herein may be provided as trenches in the saw streets 158 and/or in the upper surface 120u extending along outer edges 120e of adjacent semiconductor structures 120.

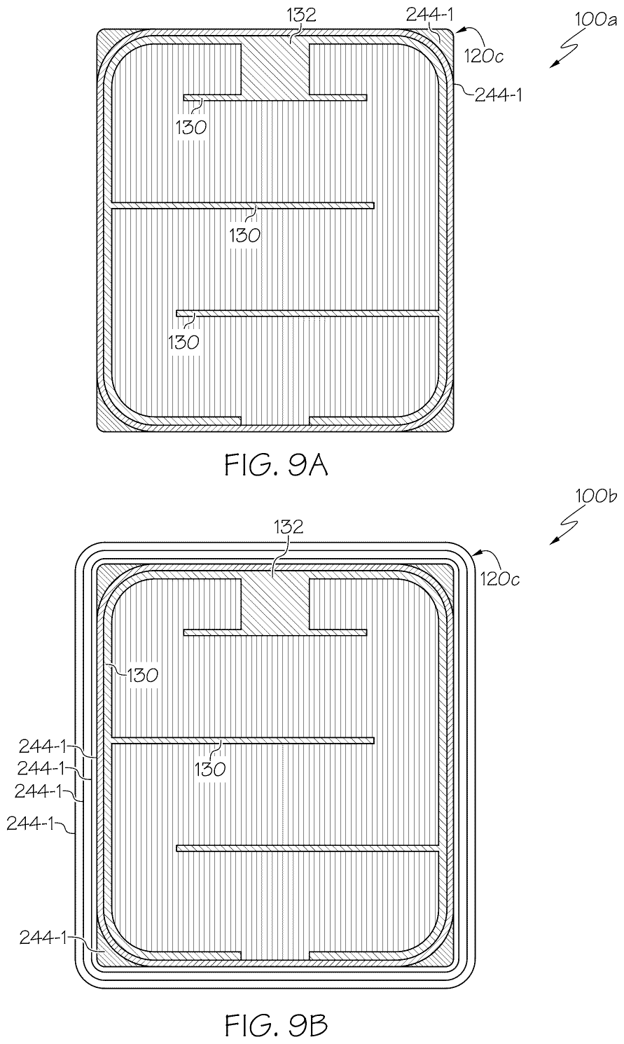

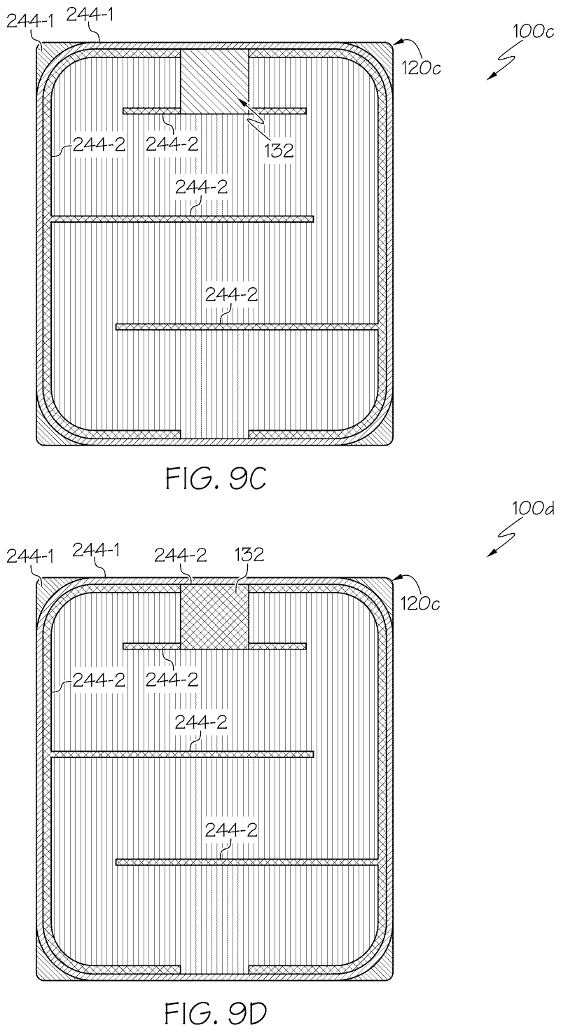

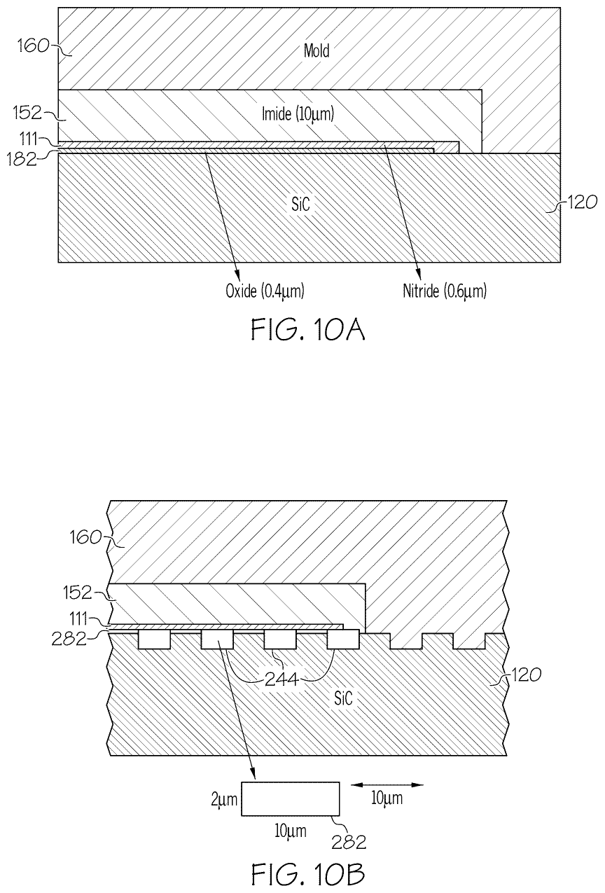

FIGS. 9A, 9B, 9C, and 9D are schematic plan views illustrating example locations of stress relief features 244 in the semiconductor structure 120 of a power semiconductor device 100 according to some embodiments of the present disclosure. In particular, FIG. 9A illustrates an example power semiconductor device 100a in which the stress relief structures 244-1 are implemented in the peripheral region 16 as curved trenches at the four corner regions 120c of the semiconductor structure 120, along with a single outer ring trench 244-1 extending around the entire semiconductor structure 120. FIG. 9B illustrates an example power semiconductor device 100b in which the stress relief structures 244-1 are similarly implemented in the peripheral region 16 as curved trenches at the four corner regions 120c of the semiconductor structure 120 (as in FIG. 9A), but with multiple outer ring trenches 244-1 extending around the entire semiconductor structure 120. As noted above, an area density of the stress relief features 244-1 may be greater at corner regions 120c than at the edge regions 120e of the semiconductor structure 120, due to differences in levels of stress that may be present in the different regions 120c, 120c.

FIG. 9C illustrates an example power semiconductor device 100c in which the stress relief structures 244-1 are implemented in the peripheral region 16 as curved trenches at the four corner regions 120c of the semiconductor structure 120 and a single outer ring trench 244-1 (as in FIG. 9A). As shown in FIG. 9C, stress relief structures 244-2 are additionally (or alternatively) implemented in electrically inactive areas adjacent portions of the active region 14 under internal conductive structures 130 (including horizontal and/or vertical gate buses, or otherwise regardless of gate bus configuration) to reduce stress under the conductive buses. FIG. 9D illustrates an example power semiconductor device 100a in which the stress relief structures 244-2 are implemented in electrically inactive areas adjacent portions of the active region 14 under internal conductive structures 130 (as in FIG. 9C), and are also provided under conductive pads 132 (e.g., under the gate pad). The stress relief structures 244-2 may thereby reduce stress that is induced or otherwise present in the active conducting area 14 of the power semiconductor devices 100c, 100d. In particular, due to topographical differences in the semiconductor structure 120 in different regions (e.g., gate trenches or planar gates in the active region 14), different regions of the semiconductor structure 120 may be subjected to different levels of stress. Locally providing stress relief structures 244-2 in such regions may thereby reduce stress (and/or may reduce stress mismatch) in the different regions of the semiconductor structure 120. For example, placement of the stress relief structures can reduce stress caused by metal lines 130, particularly metal lines with relatively high aspect ratios (e.g., gate buses with lengths (˜3-4 mm) that are significantly greater than widths (˜30 μm)), which may impart comparatively higher mechanical stress on the underlying semiconductor structure 120 than on regions that do not include high-aspect ratio metal lines 130.

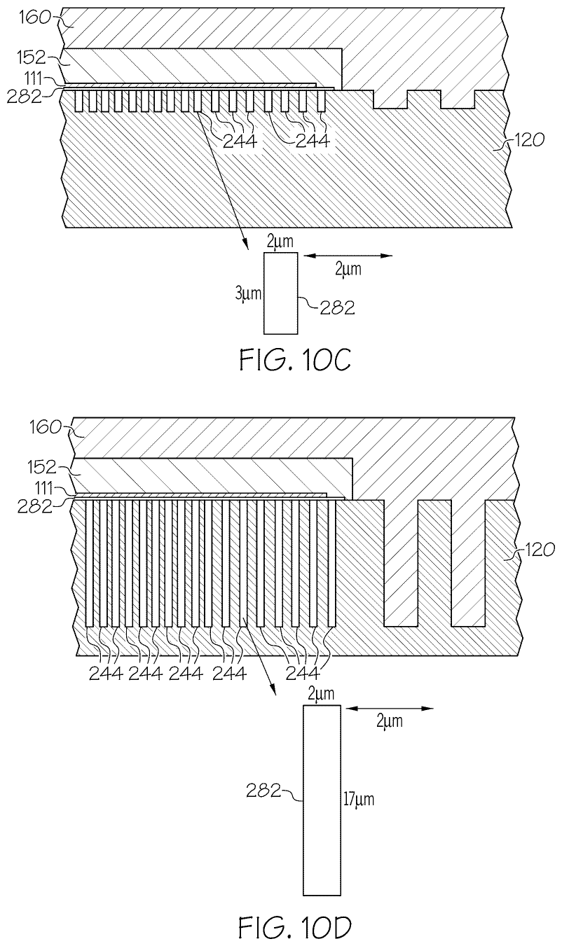

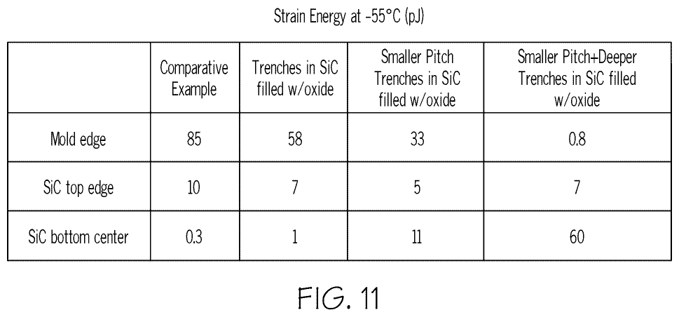

FIGS. 10A, 10B, 10C, and 10D illustrate example configurations of stress relief features according to some embodiments of the present disclosure relative to that of a comparative example and simulation data based thereon. In particular, FIG. 10A illustrates the configuration of a semiconductor structure according to a comparative example, while FIGS. 10B, 10C, and 10D illustrate configurations of stress relief features including oxide-filled trenches, oxide-filled trenches having a comparatively smaller pitch therebetween, and oxide-filled trenches having the smaller pitch and extending into the drift region with a comparatively greater depth, respectively. The inset images of FIGS. 10B, 10C, and 10D illustrate variations in stress relief trenches 244 (and oxide material 282 therein) with respect to trench depth (2 μm, 2 μm, and 17 μm, respectively), trench width (10 μm, 3 μm, and 2 μm, respectively), and trench pitch (10 μm, 2 μm, and 2 μm, respectively). FIG. 11 is a table comparing maximum strain energy (at −55 degrees Celsius in picojoules (pJ)) at various interfaces of the example configurations of stress relief features shown in FIGS. 10B to 10D with that of the comparative example shown in FIG. 10A.

As shown in FIGS. 10B to 10D and FIG. 11, stress relief features 244 according to some embodiments of the present disclosure may provide improved performance relative to the configuration shown in FIG. 10A. In particular, by decreasing the bending of the semiconductor (in these examples, SiC) structure, stress relief features 244 according to some embodiments of the present disclosure may substantially reduce delamination energy at the mold-semiconductor interface (shown in the table of FIG. 11 at both the mold edge and the corresponding top edge of the SiC structure), thereby reducing the likelihood of delamination of a mold structure 160 formed on the protective overcoating 152 and the semiconductor structure 120. As shown with respect to the configurations of FIG. 10C (smaller pitch) and 10D (smaller pitch and greater depth), the impact of the pitch of the stress relief features 244 may be less significant than the depth of the stress relief features 244 in terms of the resulting changes in delamination energy at the mold-semiconductor interface. In particular, as shown with respect to the configuration of FIG. 10D, providing stress relief features 244 with greater depth can significantly reduce delamination energy at the mold-semiconductor interface, particularly at the edges of the mold structure 160.

However, decreasing the bending of the SiC structure may increase strain energy at an underlying semiconductor-die attach interface, which is opposite the mold-semiconductor interface (shown in the table of FIG. 11 at the bottom central portion of the SiC structure). Thus, stress relief features 244 according to some embodiments of the present disclosure may increase the likelihood of semiconductor-die attach delamination, as reducing stress at one interface may result in increased stress at another. In light of this simulation data, stress relief features 244 as described herein may include depths, widths, and/or pitches that are configured to balance reduction in stress at the mold-semiconductor interface with any resulting increase in stress at the semiconductor-die attach interface.

Example applications of stress relief structures 244 as described herein may include improved and/or optimized placement of stress relief trenches to enable die that can withstand extreme thermal conditions and thus pass Temperature Cycling (TC) and High Temperature Reverse Bias (HTRB) reliability testing up to and exceeding 200° C. The stress relief structures 244 may also allow the use of a wider range of epoxy mold compound (EMC) materials for different applications and different packages, that is, EMC materials and/or packages that would otherwise be unsuitable (e.g., in terms of delamination) for a semiconductor structure 120 that does not include the stress relief features 244 described herein.

It will be understood that the arrangements of stress relief features 244 are illustrated in the drawings by way of example only, and that embodiments of the present disclosure are not limited to these particular examples. More generally, embodiments of the present disclosure may include any arrangements and/or combinations of stress relief features 244 in a semiconductor structure 120 that reduce mechanical stress in one or more regions of the semiconductor structure 120 but do not contribute to electrical conduction, independent of other electrical characteristics and/or adhesion characteristics.

Various embodiments have been described herein with reference to the accompanying drawings in which example embodiments are shown. These embodiments may, however, be embodied in different forms and should not be construed as limited to the embodiments set forth herein. Rather, these embodiments are provided so that this disclosure is thorough and complete and fully conveys the inventive concept to those skilled in the art. Various modifications to the example embodiments and the generic principles and features described herein will be readily apparent. In the drawings, the sizes and relative sizes of layers and regions are not shown to scale, and in some instances may be exaggerated for clarity.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on,” “attached,” or extending “onto” another element, it can be directly on the other element or intervening elements may also be present. In contrast, when an element is referred to as being “directly on” or “directly attached” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Elements illustrated by dotted lines may be optional in the embodiments illustrated.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

In the drawings and specification, there have been disclosed typical embodiments of the invention and, although specific terms are employed, they are used in a generic and descriptive sense only and not for purposes of limitation, the scope of the invention being set forth in the following claims.

1. A power semiconductor device, comprising:
a semiconductor structure comprising an active region; and
a plurality of stress relief trenches in the semiconductor structure laterally between the active region and at least one edge of the semiconductor structure, the stress relief trenches respectively comprising opposing sidewalls and a dielectric material and/or a semiconductor material therebetween.

2. The power semiconductor device of claim 1, wherein the stress relief trenches are arranged in a repeating pattern and do not contribute to electrical conduction between first and second terminals of the power semiconductor device.

3. The power semiconductor device of claim 2, wherein the semiconductor structure has a first conductivity type, and wherein the opposing sidewalls and/or a bottom surface of the stress relief trenches have a second conductivity type that is opposite to the first conductivity type.

4. The power semiconductor device of claim 3, wherein the stress relief trenches are in an edge termination region of the semiconductor structure.

5. The power semiconductor device of claim 2, wherein the stress relief trenches are first stress relief trenches in a peripheral region of the semiconductor structure, and further comprising:
second stress relief trenches comprising opposing sidewalls and the dielectric material and/or the semiconductor material therebetween in electrically inactive areas adjacent portions of the active region of the semiconductor structure.

6. The power semiconductor device of claim 5, further comprising:
a plurality of conductive structures on the active region, wherein the second stress relief trenches extend under the conductive structures.

7. The power semiconductor device of claim 5, wherein a depth, width, and/or pitch of the second stress relief trenches are configured such that a capacitance of the active region is substantially unaffected thereby.

8. The power semiconductor device of claim 2, further comprising:
a plurality of active trenches comprising opposing sidewalls and the dielectric material and/or the semiconductor material therebetween in the active region and configured to provide the electrical conduction between the first and second terminals of the power semiconductor device,
wherein the active trenches and the stress relief trenches extend into the semiconductor structure to a same depth.

9. The power semiconductor device of claim 1, wherein the stress relief trenches comprise a plurality of continuous tracks that extend along edges and/or corners of the semiconductor structure.

10. The power semiconductor device of claim 1, wherein the stress relief trenches comprise a plurality of discontinuous segments adjacent edges and/or corners of the semiconductor structure.

11. The power semiconductor device of claim 1, wherein a depth, width, pitch, and/or area density of a first subset of the stress relief trenches in a corner region of the semiconductor structure is greater than that of a second subset of the stress relief trenches in at least one other region of the semiconductor structure.

12. The power semiconductor device of claim 1, wherein the dielectric material comprises an oxide, a silicate glass, or air.

13. The power semiconductor device of claim 1, wherein the semiconductor material in the stress relief trenches includes a polysilicon material that defines a heterojunction with the semiconductor structure.

14. The power semiconductor device of claim 1, wherein the semiconductor material in the stress relief trenches includes one or more epitaxial layers.

15. The power semiconductor device of claim 1, wherein the power semiconductor device is a Schottky diode, a field effect transistor, or a bipolar transistor.

16. The power semiconductor device of claim 1, wherein the semiconductor structure comprises a silicon carbide substrate and/or one or more silicon carbide epitaxial layers.

17. A power semiconductor device, comprising:
a semiconductor structure comprising an active region; and
a plurality of trenches in the semiconductor structure,
wherein a first subset of the trenches is in the active region and is configured to provide electrical conduction between first and second terminals of the power semiconductor device, and
wherein a second subset of the trenches does not contribute to the electrical conduction.

18. The power semiconductor device of claim 17, wherein the first and second subsets of the trenches extend into the semiconductor structure to a same depth.

19. The power semiconductor device of claim 17, wherein the first and second subsets of the trenches have a same width and/or are spaced apart by a same pitch.

20. The power semiconductor device of claim 17, wherein the second subset of the trenches comprises first stress relief trenches in a peripheral region of the semiconductor structure that is laterally between the active region and at least one edge of the semiconductor structure.

21.-26. (canceled)

27. A power semiconductor device, comprising:
a semiconductor structure comprising a drift region having a first conductivity type; and
a plurality of stress relief features extending into the drift region with a depth, width, and/or pitch configured to vary a mechanical stress in the semiconductor structure, the stress relief features comprising regions of a second conductivity type configured to vary an electric field concentration in the semiconductor structure.

28. The power semiconductor device of claim 27, wherein the stress relief features do not contribute to electrical conduction between first and second terminals of the power semiconductor device.

29. The power semiconductor device of claim 28, wherein the stress relief features comprise first stress relief trenches having opposing sidewalls and a first dielectric material therebetween in a peripheral region of the semiconductor structure that is laterally between an active region and at least one edge of the semiconductor structure.

30. The power semiconductor device of claim 29, wherein the first stress relief trenches are in an edge termination region, and wherein the regions of the second conductivity type provide termination rings that extend along respective bottom surfaces of the first stress relief trenches between the opposing sidewalls.

31.-35. (canceled)

36. A method of fabricating a power semiconductor device, the method comprising:
providing a semiconductor structure comprising an active region;
forming a mask pattern on the semiconductor structure;
performing an etching process using the mask pattern to form a plurality of trenches in the semiconductor structure, wherein a first subset of the trenches are in the active region and a second subset of the trenches are laterally between the active region and at least one edge of the semiconductor structure.

37. The method of claim 36, wherein the second subset of the trenches does not contribute to electrical conduction between first and second terminals of the power semiconductor device.

38. The method of claim 37, wherein the semiconductor structure has a first conductivity type, and further comprising:
implanting dopants of a second conductivity type into opposing sidewalls and/or bottom surfaces of the plurality of trenches after performing the etching processes.

39.-46. (canceled)
